(19) United States
(12) Patent Application Publication
(10) Pub. No.: US 2018/0005916 A1
(43) Pub. Date: Jan. 4, 2018

(54) SEMICONDUCTOR STRUCTURE AND MANUFACTURING METHOD THEREOF

(71) Applicant: TAIWAN SEMICONDUCTOR MANUFACTURING COMPANY LTD., HSINCHU (TW)

(72) Inventors: CHIN-LIANG CHEN, KAOHSIUNG CITY (TW); CHI-YANG YU, TAOYUAN COUNTY (TW); KUAN-LIN HO, HSINCHU CITY (TW); YU-MIN LIANG, TAOYUAN COUNTY (TW)

(21) Appl. No.: 15/255,539

(22) Filed: Sep. 2, 2016

Related U.S. Application Data
(60) Provisional application No. 62/356,853, filed on Jun. 30, 2016.

(51) Int. Cl. H01L 23/367; H01L 21/78; H01L 23/31; H01L 21/683; H01L 23/498; H01L 23/00; H01L 25/065

(52) U.S. Cl. CPC H01L 23/3675; H01L 24/09; H01L 21/78; H01L 25/0655; H01L 24/17; H01L 21/6836; H01L 23/49827; H01L 23/3128; H01L 2221/68327; H01L 2224/0401

(57) ABSTRACT

The present disclosure provides a semiconductor device. The semiconductor packaged device includes a first semiconductor die having a first surface. The semiconductor packaged device also includes a dielectric material surrounding the first semiconductor die, where the dielectric material comprises a surface substantially leveled with the first surface. The semiconductor packaged device further includes a capping layer covering the first surface of the first semiconductor die and the surface of the dielectric material. An adhesivity between the capping layer and a dicing tape is lower than an adhesivity between the dielectric material and the dicing tape.

### PRIORITY CLAIM AND CROSS-REFERENCE

This application claims priority to U.S. patent application Ser. No. 62/356,853 filed Jun. 30, 2016 the disclosure of which is hereby incorporated by reference in its entirety.

### BACKGROUND

A significant trend for the integrated circuit (IC) development is the downsizing of IC components. These integration improvements are two-dimensional (2D) in nature where the ICs are formed and interconnected on a surface of a semiconductor wafer. Although dramatic improvement in lithography has enabled greater results in 2D IC formation, there are physical limits to the density that can be achieved in two dimensions. Also, when more devices are put into one chip, more complicated designs and higher costs are required.

In an attempt to further increase the circuit density, three-dimensional (3D) ICs have been developed. For example, two dies are stacked; and electrical connections are formed between each die. The stacked dies are then bonded to a carrier substrate by using wire bonds and/or conductive pads. In another example, a technique of chip-on-wafer-on-substrate (CoWoS) is developed in which dies are electrically connected to a wafer substrate followed by a bonding operation with another substrate through conductive bumps.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7 are cross-sectional views of intermediate stages for manufacturing a semiconductor packaged device in accordance with various embodiments of the present disclosure.

FIGS. 8-11 are cross-sectional views of intermediate stages for manufacturing a semiconductor packaged device in accordance with various embodiments of the present disclosure.

FIGS. 12-16 are cross-sectional views of intermediate stages for manufacturing a semiconductor packaged device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the FIGURES. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure presents a semiconductor device and manufacturing methods thereof, in which a capping layer is formed over a chip-on-wafer (CoW) die and serves as an interface layer between the Cow die and a dicing tape. The capping layer can help weakening the adherence strength between the dicing tape and the CoW dies in order to facilitating the detaching operation of the dies from the dicing tape. The intermediate stages of forming the semiconductor packaged device are illustrated. Some variations of some embodiments are also discussed. Like reference numbers are used throughout various views and embodiments to designate like elements.

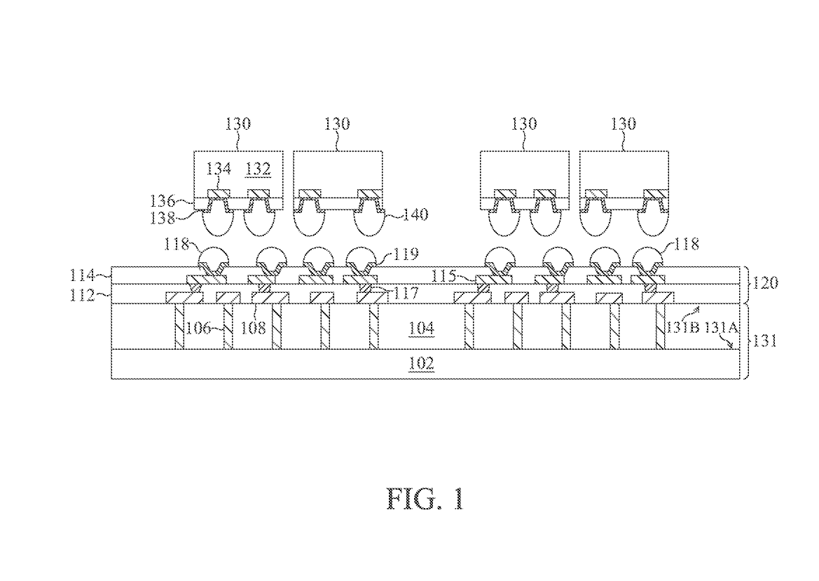

FIGS. 1-7 are cross-sectional view of intermediate stages for manufacturing a semiconductor packaged device in accordance with various embodiments of the present disclosure. In some embodiments, FIGS. 1-7 are cross-sectional view of intermediate stages for a manufacturing process with respect to a CoW process, resulting in CoW dies.

Referring to FIG. 1, there are shown a wafer 131 and several semiconductor dies 130 for the CoW process. Dies 130 are disposed in groups and each group may be arranged as an array of identical semiconductor dies. Alternatively, the dies 130 within a group may be a collection of different semiconductor dies with different structures and functions. For example, each group of dies 130 may comprise a microprocessor device with programmable memory storage such as flash or EEPROM devices, or microprocessors with application specific processors such as baseband transceivers, graphics processors, cache memory devices, memory management devices, and analog to digital converters for sensor applications.

Each die 130 comprises a substrate (or called die substrate) 132. The substrate 132 includes a semiconductor material, such as silicon. In one embodiment, the substrate 132 may include other semiconductor materials, such as silicon germanium, silicon carbide, gallium arsenide, or the like. The substrate 132 may be a p-type semiconductive substrate (acceptor type) or n-type semiconductive substrate (donor type). Alternatively, the substrate 132 includes another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs GaInAs, GaInP, and/or GaInAsP; or combinations thereof. In yet another alternative, the die substrate 132 is a semiconductor-on-insulator (SOI). In other alternatives, the substrate 132 may include a doped epi layer, a gradient semiconductor layer, and/or a semiconductor layer overlying another semiconductor layer of a different type, such as a silicon layer on a silicon germanium layer.

Various components, such as active devices, passive components, conductive portions or insulating materials may be formed in the die substrate 132. In addition, each die 130 comprises one or more connection terminals 134, which refer to as conductive pads or bond pads. The embedded components of the die substrate 132 are electrically coupled to external circuits or devices through the connection terminals 134.

A dielectric layer 136 or a passivation layer is deposited on the connection terminals 134. The dielectric layer 136 may be provided by initially forming a blanket layer through a suitable process, such as chemical vapor deposition (CVD), physical vapor deposition (PVD), atomic layer deposition (ALD), or the like. Later, lithographic and etching processes are performed on a photoresist (not separately shown) in order to expose the connection terminal 134, thus forming respective openings thereon. The undesired portion of the dielectric material is removed, resulting in the dielectric layer 136 as shaped. The dielectric layer 136 may be formed with a variety of dielectric materials and may, for example, be an oxide (e.g., Ge oxide), an oxynitride (e.g., GaP oxynitride), silicon dioxide (SiO₂), a nitrogen-bearing oxide (e.g., nitrogen-bearing SiO₂), a nitrogen-doped oxide (e.g., N₂-implanted SiO₂), silicon oxynitride (SiₓO_{y}N_{z}), a polymer material, and the like.

Moreover, a conductive layer is deposited on the connection terminal 134 and then patterned to form an under bump metallization (UBM) 138, which is also referred to as ball-limiting metallurgy (BLM). The UBM 138 defines a size of a connector, such as a conductive bump, to be formed thereon after a reflow operation, and reacts with the connector so as to provide effective adhesion and a barrier between the connector and underlying structures. In the present embodiment, the UBM 138 provides additional adhesion between the connection terminals 134 and connectors 140. In some embodiments, the UBM 138 may increase solderability of the connectors 140. Materials of the UBM 138 include, for example, titanium (Ti), tantalum (Ta), titanium nitride (TiN), tantalum nitride (TaN), copper (Cu), copper alloys, nickel (Ni), tin (Sn), gold (Au), or combinations thereof. In some embodiments, the UBM 138 comprises a layered structure comprising different conductive material sublayers.

The connectors 140 are formed subsequent to the formation of the UBM 138. The connectors 140 are formed of conductive materials, such as tin, copper, nickel, or the like. The connectors 140 may be implemented as conductive bumps, such as micro bumps, or controlled collapse chip connection (C4) bumps. The connectors 140 are formed by any suitable operations, such as dropping balls, solder paste in a screen printing operation, electroless or electroplating approaches, controlled collapse chip connection (C4) plating or C4NP (C4 New Process) solder transfers.

The wafer 131 comprises substrate materials of, for example, silicon or other suitable substrate materials 104 such as ceramic, glass, plastic, resin or epoxy. In addition, the wafer 131 includes through substrate vias (TSVs) 106 running along a vertical direction substantially perpendicular to the surface of the wafer 131. In an embodiment, the TSVs 106 may extend from a first surface 131A to a second surface 131B, where the TSVs 106 are also regarded as through interposer vias (TIV) if the wafer 131 is diced. In an embodiment, the wafer 131 is an interposer wafer, providing interconnection features for adjacent dies or devices. In an embodiment in which the wafer 131 is an interposer wafer, there may be no active or passive devices formed in the wafer, except for the TSVs 106.

In an embodiment, a carrier 102 is disposed under the wafer 131. The carrier 102 holds and supports the wafer 131 for the subsequent processes, and may be thinned, removed, or released from the wafer 131 in subsequent operations. The carrier 102 is made of any strippable or easily removed material, for example, films, tapes, liquid adhesives and the like.

A redistribution layer (RDL) 120 is formed over the second surface 131B of the wafer 131. The RDL 120 includes patterned conductors 108 and 117, and at least one dielectric layer 112. The dielectric layer 112 is used for electrically insulating the conductive features 108 and 117. The dielectric layer 112 is made of dielectric material including, for example, oxide or nitride. The patterned conductors 108 and 117 are arranged as laterally extending conductive lines 108 and vertically extending conductive vias 117, and collectively constitute a re-routed conductive layout for the dies 130. Further, the conductive lines 108 are coupled with the TSVs 106 in order to create an electrical connection. The conductive lines 108 and 117 are made of conductive material suitable for interconnection, for example, copper, silver, aluminum, tungsten, a combination thereof, of the like. By using the RDL 120, changes of the dies 130 or the conductive bump patterns are made without modifying the system board since the dies 130 are allowed to communicate each other through the RDL 120. The RDL 120 thus is able to change the layout of new dies or new bump patterns for particular functions. This flexibility saves cost and allows any changes of dies or die vendors. In the present embodiment, one layer of conductive lines 108 is shown for illustrated purposes only. Variations and modifications for the RDL 120 are within the contemplated scope of the present disclosure, such as more layers of conductive lines interconnected through conductive vias 117 and more layers of dielectric materials 112 formed therebetween.

Another conductive layer is formed in the RDL 120 and then patterned to form conductive pads 115. The conductive pads 115 are made of conductive material, for example, aluminum, copper, copper alloys, or nickel. Later, a dielectric layer 114, which may serve as a protection layer of the RDL 120, is formed on the conductive pads 115. The dielectric layer 114 may be formed by, for example, chemical vapor deposition (CVD), atomic layer deposition (ALD), spin coating, evaporation, or the like. Later, lithographic and etching processes are performed to expose the conductive pads 115, thus forming openings. A conductive layer is disposed on the conductive pads 117 and then patterned to form a UBM 119. The UBM 119 is in contact with the conductive pads 115 and supported by the dielectric layer 114.

Connectors 118 are formed on the UBM 119 of the RDL 120. The connectors 118 are used for electrically couple external devices, such as dies 130 with the wafer 131. The connectors 118 may be implemented as conductive bumps, such as micro bumps, or controlled collapse chip connection (C4) bumps. The connectors 118 are formed of conductive materials, such as tin, copper, nickel, or the Like. The connectors 118 may be formed by evaporation, an electroplating process, dropping balls, solder paste in a screen printing operation, electroless or electroplating approaches, C4 plating or C4NP solder transfers. Once formed, the connectors 118 are aligned with the corresponding connectors 140 of the respective dies 130, in order to aid the subsequent bonding operation.

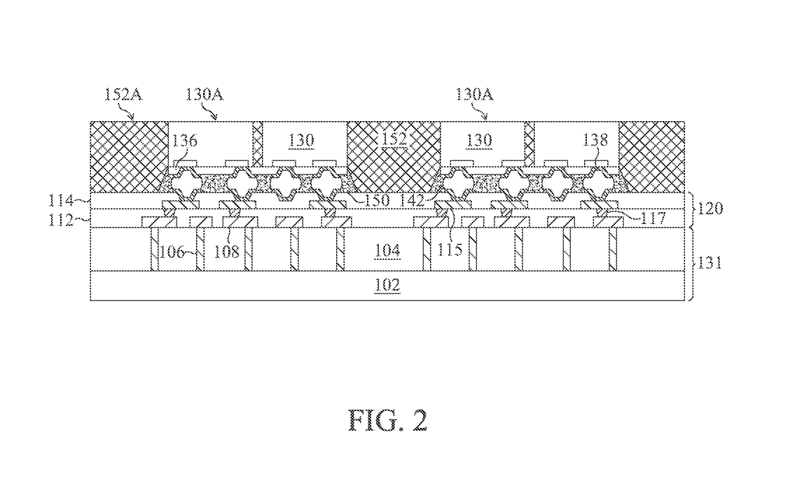

Referring to FIG. 2, the dies 130 are bonded to the wafer 131 through respective connectors 142. The bonding operation may be performed in a variety of processes. For example, a thermal reflow process is used to cause the connectors 140 and 118 in FIG. 1 to be softened. After a period of cooling, the connectors 140 and 118 are melted, and merged connectors 142 are formed accordingly between the dies 130 and the wafer 131. The connectors 142 provide an attachment and an electrical connection between the dies 130 and the wafer 131. In some embodiments, the connectors 142 may be conductive bumps, such as micro bumps or controlled collapse chip connection (C4) bumps. In some embodiments, the connectors 142 are formed with spherical shapes or non-spherical shapes.

Following the formation of the connectors 142, an underfill layer 150 fills some spaces between the dies 130 and the wafer 131. In some embodiments, the underfill layer 150 fills a gap between the connectors 142. In some embodiments, the underfill layer 150 covers an upper surface of the RDL 120. In some embodiments, the underfill layer 150 comprises a sidewall meeting a sidewall of the die 130. The underfill layer 150 provides a flexible compliant material surrounding the connectors 142 and an adhesion between the dies 130 and the wafer 131. Further, the underfill layer 150 provides a stress relief during thermal cycling so as to prevent the connectors 142 and the dies 130 from cracking.

In some cases, the underfill layer 150 comprises a dielectric material, and may be selected from encapsulating or molding materials. In some embodiments, the underfill layer 150 includes, for example, compliant epoxies that are liquid at temperatures above room temperature, and have rapid cure times especially at elevated temperatures and low viscosity during dispensing. In some embodiments, syringes or needles are utilized in dispensing the dielectric material of the underfill layer 150.

In some embodiments, the underfill layer 150 includes a first surface, which is adjacent to the RDL 120, being larger than a second surface, which is adjacent to the dies 130. In some embodiments, the underfill layer 150 includes a tapered sidewall. In an embodiment, the underfill layer 150 may include a sidewall that slopes up from the dielectric layer 114 to the dielectric layer 136, thus sealing the gaps between the dies 130 and the wafer 131.

Still referring to FIG. 2, a dielectric material 152 is formed over the RDL 120 of the wafer 131 and surrounds the dies 130. The dielectric material 152 may be formed as an encapsulating layer surrounding the dies 130, the connectors 142 or the RDL 120. In accordance with some embodiments, the dielectric material 152 covers the dielectric layer 136 and sidewalls of the dies 130. In accordance with some embodiments, the dielectric material 152 covers a sidewall of the underfill layer 150. In some embodiments, the dielectric material 152 surrounds a perimeter of each of the dies 130.

The dielectric material 152 may be a molding compound resin such as polyimide, polyphenylene sulphide (PPS), polyether ether ketone (PEEK), polyethersulfone (PES), a heat resistant crystal resin, or combinations thereof. In some embodiments, the dielectric material 152 may be formed with a variety of dielectric materials and may, for example, be an oxide (e.g., Ge oxide), an oxynitride (e.g., GaP oxynitride), silicon dioxide (SiO₂), a nitrogen-bearing oxide (e.g, nitrogen-bearing SiO₂), a nitrogen-doped oxide (e.g., N₂-implanted SiO₂), silicon oxynitride (SiₓO_{y}N_{z}), and the like. In some embodiments, the dielectric material 152 may be a protective material such as polybenzoxazole (PBO), polyimide (PI), benzocyclobutene (BCB), silicon oxide, silicon nitride, silicon oxynitride, or any other suitable protective material.

In some cases, a portion of the dielectric material 152 is removed in an operation, which is referred to as a backside grinding process. An upper surface 152A of the dielectric material 152 is planarized in which excessive molding materials are ground by a planarization process, such as chemical mechanical polishing (CMP) operation or other mechanical processes. Accordingly, an upper surface 130A of each of the dies 130 is exposed. In some embodiments, the upper surface 130A is leveled with the upper surface 152A. In some embodiments, the upper surface 130A meets with the upper surface 152A. In other words, the upper surfaces 130A and 152A are arranged in a coplanar fashion.

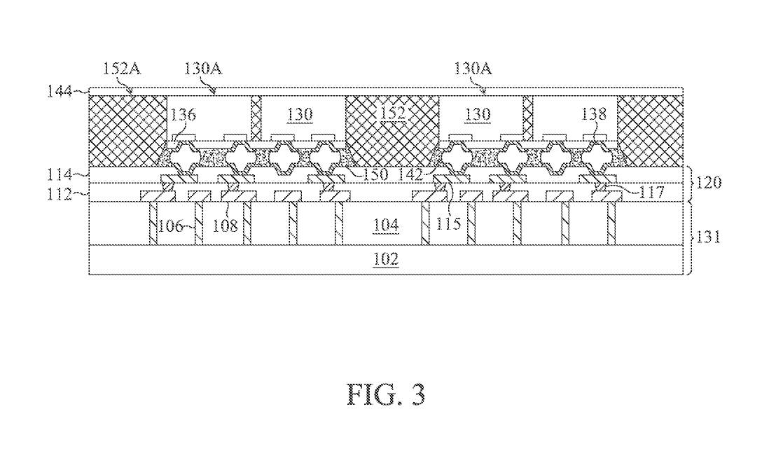

Referring to FIG. 3, a capping layer 144 is formed over the dielectric material 152 and the dies 130. In some embodiments, the capping layer 144 covers a surface composed of the upper surface 130A of the die 130 and the upper surface 152A of the dielectric material 152. The capping layer 144 may be formed to fully cover each of the upper surface 130A of the dies 130. In an embodiment, the capping layer 144 extends continuously over the group of dies 130. Therefore, the capping layer 144 covers an upper surface between the dies 130. The capping layer 144 is partially in contact with the dies 130 and partially in contact with the dielectric layer 152.

The capping layer 144 may be formed of a homogeneous material. In some embodiments, the capping layer 144 is formed of a conductive material such as Ti, Cu, Ni, Al, Ag, a combination thereof, alloys thereof, or other suitable materials. In some embodiments, the capping layer 144 is formed of metallic-based or solder-based materials, such as aluminum oxide, boron nitride, aluminum nitride, or the like. The capping layer 144 may be formed by using a variety of techniques, such as high-density ionized metal plasma (IMP) deposition, high-density inductively coupled plasma (ICP) deposition, sputtering, PVD, CVD, low-pressure chemical vapor deposition (LPCVD), plasma-enhanced chemical vapor deposition (PECVD), electrochemical plating, electroless plating, and the like.

In an embodiment, the capping layer 144 is a thin film and serves as an interface layer between a hetero-surface and an overlying component. The hetero-surface may include upper surface 130A of the dies 130 and upper surface 152A of the dielectric layer 152. In an embodiment, the capping layer 144 may not provide any electrical connections to the dies 130, and thus may be electrically insulated from the dies 130 or the dielectric material 152. In some embodiments, the capping layer 144 may be formed with a thickness sufficient to assist in adherence to the dies 130 or the dielectric material 152. In some embodiments, the capping layer 144 is formed to a thickness from about 0.05 μm to about 3.0 μm. In some embodiments, the capping layer 144 is formed to a thickness from about 0.1 μm to about 1.0 μm. In some embodiments, the capping layer 144 is formed to a thickness from about 0.1 μm to about 0.5 μm.

In an embodiment, the capping layer 144 can additionally benefit heat dissipation of the dies 130. In an embodiment where the capping layer 144 is in contact with the dies 130, heat generated by the dies 130 can be dissipated through the capping layer 144 effectively. In some embodiments, the capping layer 144 comprises a thermal conductivity greater than about 100 Watt/m*K. In some embodiments, the capping layer 144 comprises a thermal conductivity greater than about 400 Watt/m*K. In some embodiments, the capping layer 144 comprises a thermal conductivity between about 100 Watt/m*K and about 400 Watt/m*K.

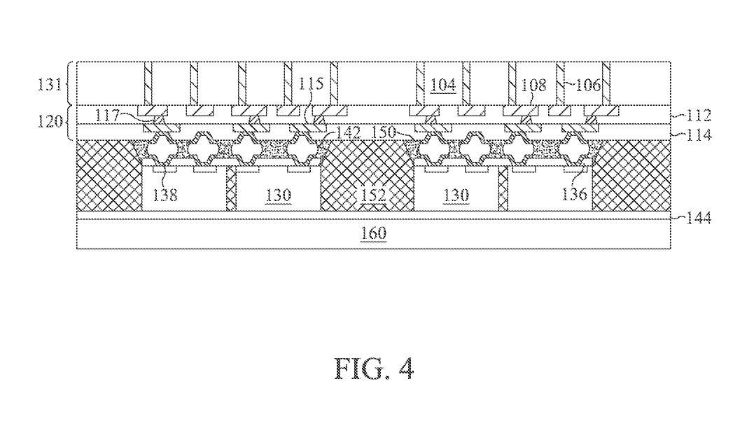

Subsequently, as shown in FIG. 4, the bonded structure of FIG. 3 is flipped over and another carrier 160 is provided for supporting the bonded structure. In addition, the carrier 102 in FIG. 3 is released or removed from the wafer 131. In some embodiments where the TSVs 106 are buried in the substrate material 104 of the wafer 131, a recessing or thinning operation may be performed in order to expose the TSVs 106 from a surface of the wafer 131. The thinning operation may include an etching operation, such as a dry etching or wet etching operation, a grinding, or a CMP process.

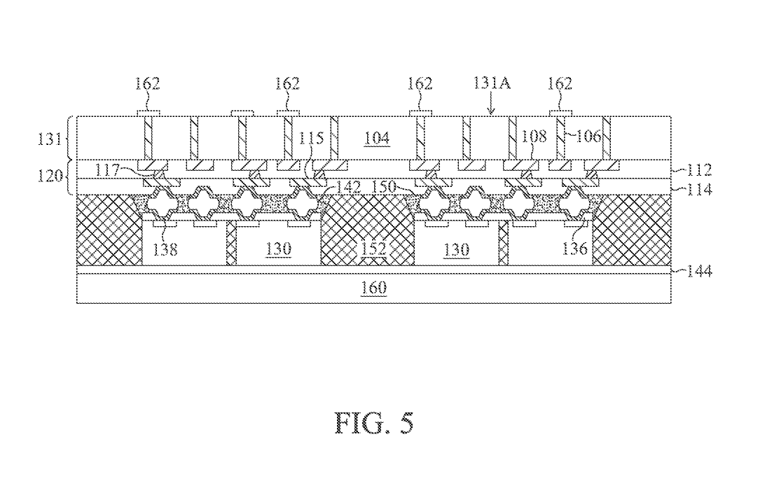

Referring to FIG. 5, conductive pads 162 are formed over the respective exposed TSVs 106. In some embodiments, the conductive pads 162 are formed of a conductive material such as aluminum, copper, tungsten, or the like. The conductive pads 162 may be formed using a process such as CVD or PVD, although other suitable materials and methods may alternatively be utilized. As an exemplary operation, the formation for the conductive pads 162 may be performed by initially forming a conductive layer over the exposed surface 131A of the wafer 131. Then, a patterned photoresist (not separately shown) is formed or disposed over the conductive layer. The conductive pads 162 are formed by removing undesired portions of the conductive layer with the photoresist as a patterning mask. Additionally, subsequent to the formation of the conductive pads 162, a removal operation may be performed, for example by using an etching process, for removing the patterned photoresist.

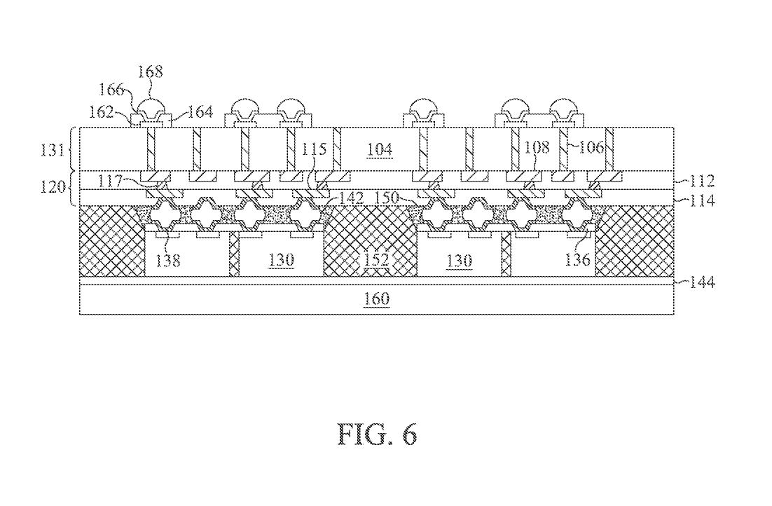

In FIG. 6, a dielectric layer 164 may be formed over the conductive pads 162. In some embodiments, the dielectric layer 164 is patterned so as to have openings to expose the conductive pads 162. In some embodiments, the dielectric layer 164 may be formed as a passivation layer. The patterned dielectric layer 164 may be formed by a variety of techniques, e.g., CVD, LPCVD, PECVD, sputtering and physical vapor deposition, thermal growing, and the like. The patterned dielectric layer 106 may be formed with a variety of dielectric materials and may, for example, be an oxide (e.g., Ge oxide), an oxynitride (e.g., GaP oxynitride), silicon dioxide (SiO₂), a nitrogen-bearing oxide (e.g., nitrogen-bearing SiO₂), a nitrogen-doped oxide (e.g., N₂-implanted SiO₂), silicon oxynitride (SixOyNz), and the like.

Furthermore, several connectors 168 are formed over the conductive pads 162. The connectors 168 electrically couple the TSVs 106 with external components or devices through the conductive pads 162. The connectors 168 may be contact bumps such as controlled collapse chip connection (C4) bumps, ball grid array bumps or microbumps. The connectors 168 may comprise a conductive material such as tin, copper, tungsten, gold, silver, nickel, or the like. In accordance with some embodiments, a UBM 166 is formed between respective dielectric layer 164 and the connectors 168. The materials and formation processes for the UBM 166 may be similar to those UBMs as described and illustrated in FIG. 1, such as the UBM 138 for formation of the connectors 140 or the UBM 119 for the connectors 118.

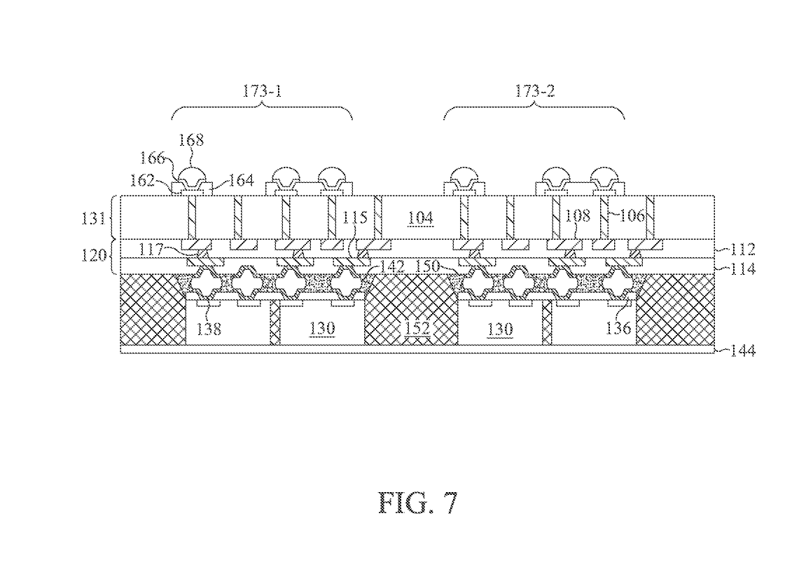

Referring to FIG. 7, the carrier 160 in FIG. 6 is removed from the bonded semiconductor structure 173. The bonded semiconductor structure 173 comprising the dies 130 with the wafer 131, as shown in FIG. 7 can be referred as CoW dies (e.g., dies 173-1 and 173-2), which are available for subsequent operations for forming a CoW-on-substrate (CoWoS) package.

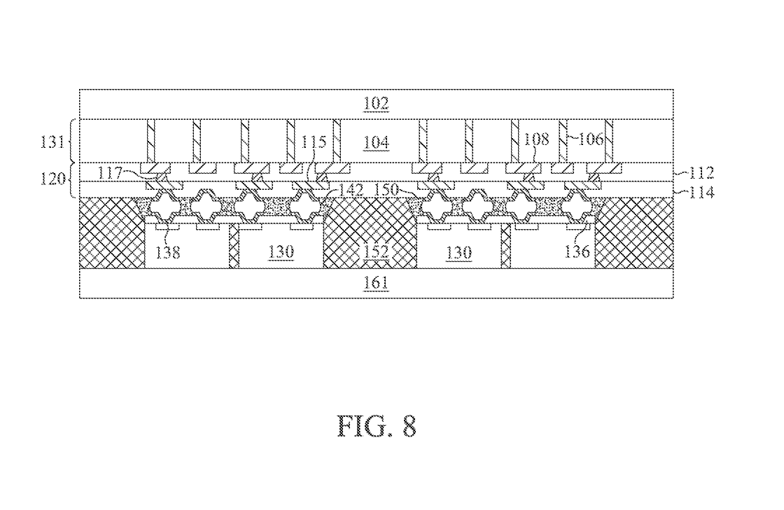

Another embodiment for manufacturing a semiconductor packaged structure in accordance with various operations are shown in the following with reference to the cross-sectional views in FIGS. 1-2 and followed by FIGS. 8-11. Like reference numerals in different figures illustrating cross-sectional views for different operations may represent like elements.

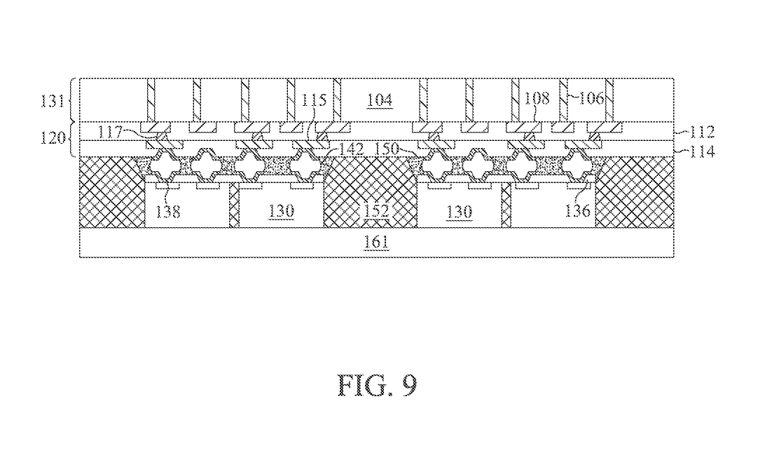

Referring to FIG. 8, the bonded structure shown in FIG. 2 is flipped over and disposed over another carrier 161. Once the bonded structure is in place, the wafer 131 is thinned so as to expose the TSVs 106, as illustrated in FIG. 9. In an embodiment, the carrier 102 is initially removed or released from the wafer 131, followed by a recessing operation for the substrate material 104. Accordingly, a top portion of the TSV 106 is exposed from the wafer 131.

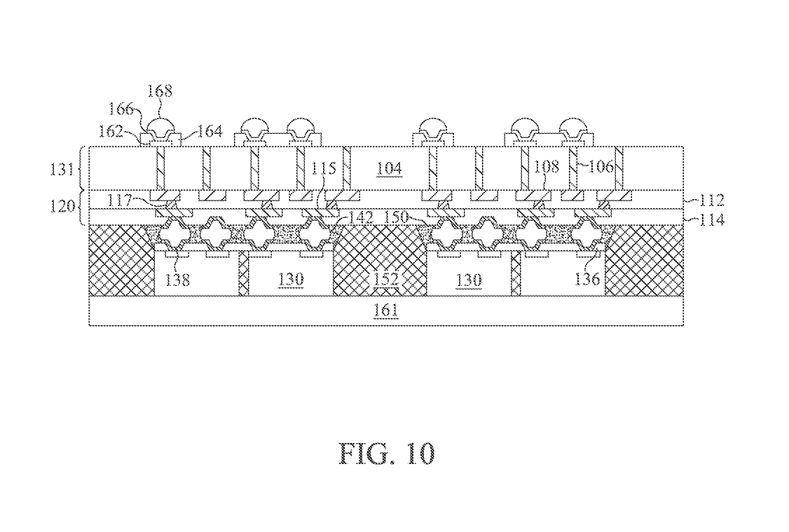

In FIG. 10, the conductive pads 162, the dielectric layer 164 and the UBM 166 are sequentially formed over one another. The materials and formation operations for the conductive pads 162, the dielectric layer 164 and the UBM 166 used in the present embodiment may be similar to those like elements described and illustrated in FIGS. 5-6.

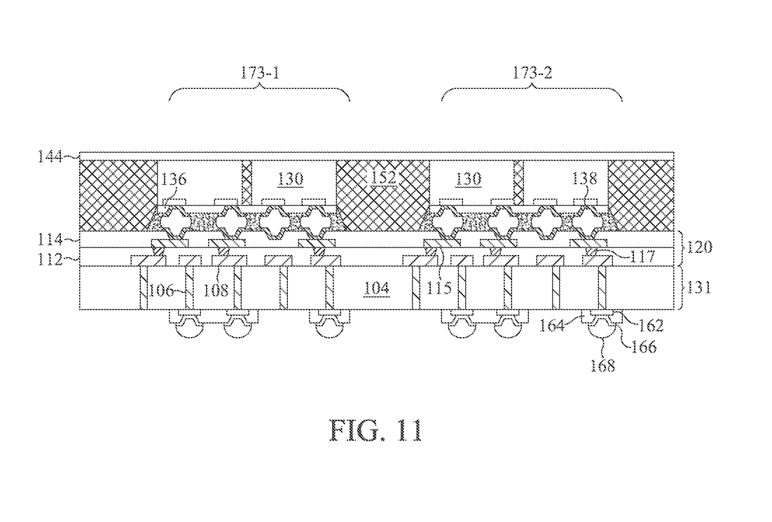

FIG. 11 illustrates a schematic cross-sectional view of removal of the carrier 161. Further, the bonded structure of the dies 173 is flipped and then placed over a support member or disposed in a chamber (not separately shown). In an embodiment, one or more cleaning operations may be performed by using cleaning chemicals or deionized (DI) water. In addition, a capping layer 144 is formed over the dielectric material 152 and the dies 130. The materials and formation operations for the capping layer 144 used in the present embodiment may be similar to those like elements described and illustrated in FIG. 3. In an embodiment, the dies 173 may be flipped over again such that the capping layer 144 can be facing a tape, which tape would be introduced later on.

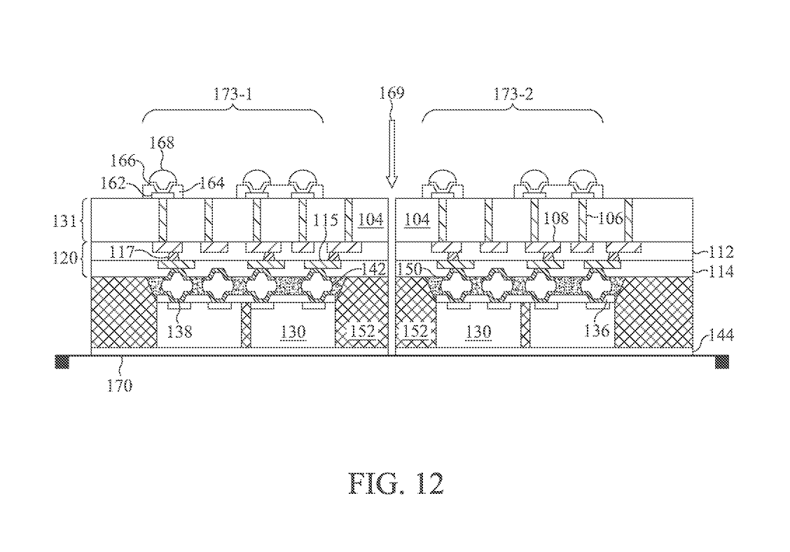

Next, the CoW dies 173 are disposed over a tape 170 as illustrated in FIG. 12. In some embodiments, the tape 170 can be a die attach film (DAF), a dry film or a dicing tape. The tape 170 comprises adhesive materials to hold and fix the dies 173. The dies 173 are attached to the tape 170 through the capping layer 144. In an embodiment, the tape 170 attaches to the dies 173 at the capping layer 144. Next, a dicing or singulation operation is performed against the CoW dies 173. In some embodiments, the dicing operation is performed by using a dicing blade 169. However, a laser may be alternatively used for performing the singulation operation. Accordingly, each of the singulated CoW dies 173 includes a group of dies 130 and a corresponding segmented wafer 131, which may also be referred to as an interposer substrate 131. As a result, a singulated CoW die 173 comprises dies 130 along with corresponding interposer substrates 131, and may further include other features such as RDL 120, connectors 142, conductive pads 162, etc. as described and illustrated in FIGS. 1 through 6.

Still referring to FIG. 12, once the singulation operation is completed, CoW dies 173 are cut and separated from each other. A breaking mechanism used in the singulation operation may cut through the wafer 131, the dielectric layers 112 and 114, the dielectric material 152, and possibly through a depth of the tape 170. Furthermore, the breaking mechanism may cut through the capping layer 144 between the tape 170 and the dielectric material 152. Since both of the dielectric material 152 and the capping layer 144 are already formed prior to the singulation operation, a sidewall of the dielectric material 152 and a sidewall of the capping layer 144 for the respective CoW die 173 are formed during a same breaking action. In an embodiment, for a respective CoW die 173-1 or 173-2, a sidewall of the dielectric material 152 is aligned with a sidewall of the capping layer 144. Similarly, for a respective CoW die 173-1 or 173-2, in an embodiment, a sidewall of the capping layer 144 is aligned with a sidewall of the RDL 120. In an embodiment, a sidewall of the capping layer 144 is aligned with a sidewall of the interposer substrate 131.

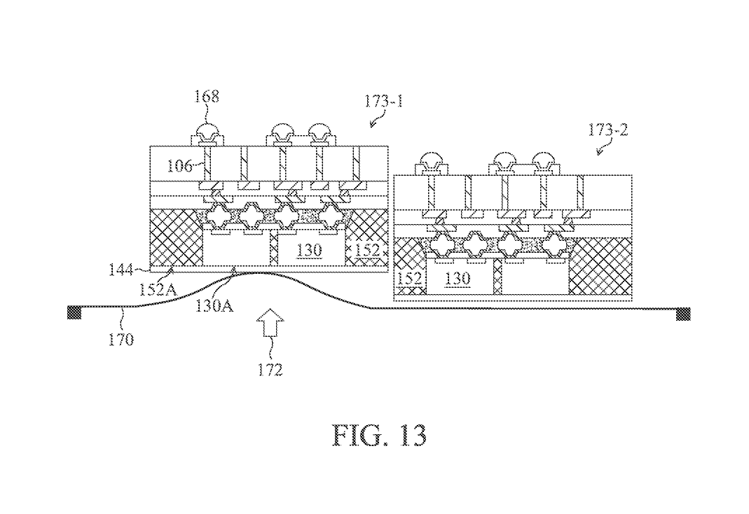

In FIG. 13, the individual CoW dies 173 (either the die 173-1 or 173-2) are lifted from the tape 170 by using a detaching tool. In some embodiments, a pick and place tool may be used for picking up the individual CoW die 173 and moving it away from the tape 170. As an exemplary embodiment, a suction mechanism or an ejection pin may be utilized to raise a target die 173. The capping layer 144 of the respective die 173 may be detached from the tape 170 by the help of the detaching tool. The adherence property between the tape 170 (e.g., a dry film) and the capping layer 144 determines the probability of successful detachment of the CoW dies 173. In some embodiments the surface energy between the capping layer 144 and the tape 170 is managed to be optimized so as to facilitate the detaching processes. In some embodiments, an adhesivity between the capping layer 144 and the dicing tape 170 is lower than an adhesivity between the dielectric material 152 and the dicing tape 170.

In some embodiments, the material for the capping layer 144 is chosen to be free of cross linking with the tape 170. The cross linking may be formed during room or elevated temperature. In some embodiments, the material for the capping layer 144 is chosen to have less cross linking with the tape 170 than what the dielectric material 152 has.

In an existing process for manufacturing a package structure, the tape 170 is directly in contact with the surface 130A of the dies 130 and the surface 152A of the dielectric layer 152 (i.e., in the absence of the capping layer 144). The adhesion force may not be uniform across the contact surface of the tape 170 due to different adherence forces with respect to different materials. For example, the surface 130A is usually made of silicon-based material, whose adhesion force (or release force) is about 50 mN/20 mm. In addition, the dielectric material 152 may comprise an adhesion force of about 290 mN/20 mm. In view of above, an undesired adherence between the dielectric material 152 and tape 170 may lead to a detachment failure. On the contrary, a capping layer 144 including, for example, nickel may provide an adhesion force of about 20 mN/20 mm. Thus, the introduction of the capping layer 144 can provide a uniform low adherence force between the CoW die and the tape 170. The capping layer 144 separates the dielectric material 152 from tape 170 so as to prevent stickiness between the dielectric material 152 and tape 170. The de-attachment process can be improved accordingly.

In an embodiment, a surface energy between the capping layer 144 and a dry film 170 is different from a surface energy between the dielectric material 152 and the dry film 170. In an embodiment, a surface energy between the capping layer 144 and the dry film 170 is smaller than a surface energy between the dielectric material 152 and the dry film 170.

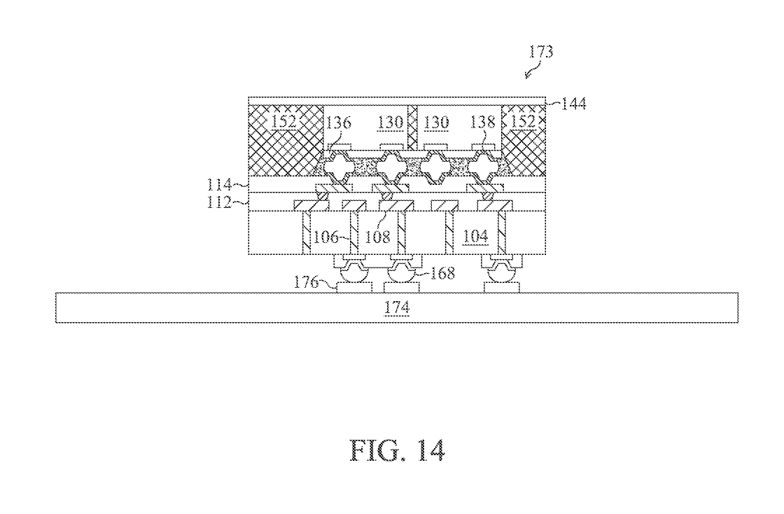

Referring to FIG. 14, another substrate 174 is provided. The substrate 174 includes a semiconductor material, such as silicon. In one embodiment, the substrate 174 may include other semiconductor materials, such as silicon germanium, silicon carbide, gallium arsenide, or the like. In the present embodiment, the substrate 174 is a p-type semiconductive substrate (acceptor type) or n-type semiconductive substrate (donor type). Alternatively, the substrate 174 includes another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In yet another alternative, the substrate 174 is a semiconductor-on-insulator (SOI). In other alternatives, the substrate 174 may include a doped epi layer, a gradient semiconductor layer, and/or a semiconductor layer overlying another semiconductor layer of a different type, such as a silicon layer on a silicon germanium layer.

Additionally, several conductive pads 176 are formed over a top surface of the substrate 174. The CoW die 173 is electrically bonded to the conductive pads 176 of the substrate 173 through the connectors 168. The bonded structure in FIG. 14 represents a CoW-on-Substrate (CoWoS) package device.

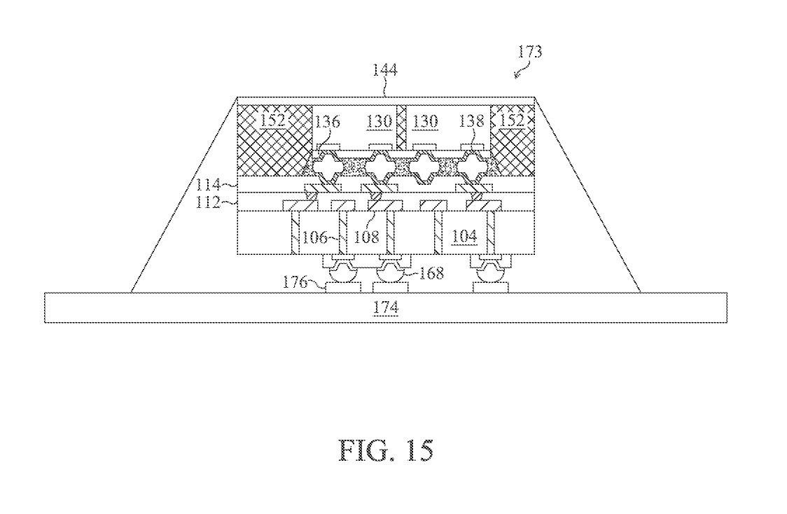

Referring to FIG. 15, a dielectric layer 178 encapsulates the CoWoS structure. In an embodiment, the dielectric layer 178 laterally surrounds the CoW die 173, the connectors 168 and the conductive pads 176. In some embodiments, the dielectric material 178 is surrounding and in contact with the capping layer 144. In some embodiments, the dielectric material 178 covers a sidewall of the capping layer 144. In an embodiment, the dielectric material 178 comprises a sidewall extending from a top surface 174A of the substrate 174 to an upper surface 144A, facing away from the die 130, of the capping layer 144.

The dielectric material 178 may be an underfill material. Alternatively, the dielectric material 178 may be a molding compound resin such as polyimide, PPS, PEEK, PES, a heat resistant crystal resin, or combinations thereof. In some embodiments, the dielectric material 178 may be an oxide (e.g., Ge oxide), an oxynitride (e.g., GaP oxynitride), silicon dioxide (SiO₂), a nitrogen-bearing oxide (e.g., nitrogen-bearing SiO₂), a nitrogen-doped oxide (e.g., N₂-implanted SiO₂), silicon oxynitride (SiₓO_{y}N_{z}), and the like.

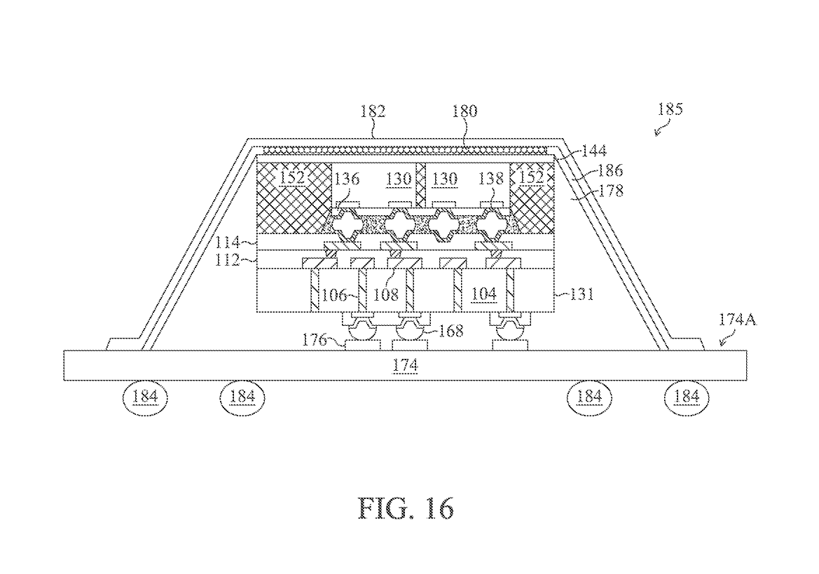

In FIG. 16, a thermal interface material (“TIM”) 180 is disposed over the capping layer 144. The TIM 180 may be dispensed after the CoW die 173 is molded by the dielectric material 178. The TIM 180 may be formed of a thermal conductive material. For example, the TIM 180 is formed of a phase change material and may change to a quasi-liquid phase when heated under a normal working temperature of the dies 130. In contrast, the material of the capping layer 144 is selected such as not to result in phase change under the range of working temperatures for the dies 130. In an embodiment, the TIM 180 comprises a melting temperature less than the capping layer 144.

Furthermore, in an embodiment, a heat spreader 182 is disposed over the TIM 180. The TIM 180 may be sandwiched between the heat spreader 182 and the capping layer 144. In an embodiment, when heated and melted, the TIM 180 is allowed to flow in a space 186 defined by the capping layer 144, the dielectric material 178, the heat spreader 182 or the substrate 174. In an embodiment, the space 186 may extend towards the upper surface 174A of the substrate 174. In some embodiments, the heat spreader 182 covers the CoW die 137, the TIM 180, the dielectric layer 178, and the substrate 174. The use of the heat spreader 182 or the TIM 180 improves the thermal performance of a packaged CoWoS die 185 and decreases the working temperatures of the dies 130.

In some embodiments, connectors 184 are formed on a bottom surface 174B of the substrate 174, where the surface 174B is facing away from the CoW die 173. The connectors 184 may be formed as micro bumps, controlled collapse chip bumps or ball grid array (BGA) bumps and may be connected to another semiconductor die, device or printed circuit board.

The present disclosure provides a semiconductor device. The semiconductor packaged device includes a first semiconductor die having a first surface. The semiconductor packaged device also includes a dielectric material surrounding the first semiconductor die, where the dielectric material comprises a surface substantially leveled with the first surface. The semiconductor packaged device further includes a capping layer covering the first surface of the first semiconductor die and the surface of the dielectric material. An adhesivity between the capping layer and a dicing tape is lower than an adhesivity between the dielectric material and the dicing tape.

The present disclosure provides a semiconductor packaged device. The semiconductor packaged device a semiconductor die. The semiconductor packaged device further includes a first dielectric material surrounding the semiconductor die laterally and including a sidewall facing away from the semiconductor die. The semiconductor packaged device also includes a capping layer covering an upper surface of the first dielectric material, where a sidewall of the capping layer is aligned with the sidewall of the first dielectric material. An adhesivity between the capping layer and a dicing tape is lower than an adhesivity between the dielectric material and the dicing tape.

The present disclosure provides a method of manufacturing a semiconductor package, the method comprising: providing a semiconductor die; encapsulating the semiconductor die laterally; forming a layer on an upper surface of the semiconductor die and an upper surface of the dielectric material where an adhesivity between the capping layer and a dicing tape is lower than an adhesivity between the dielectric material and the dicing tape; attaching the semiconductor die to the dicing tape via the layer and performing singulation against the semiconductor die; and removing the singulated semiconductor die from the tape.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor packaged device, comprising:
a first semiconductor die comprising a first surface;
a dielectric material surrounding the first semiconductor die, the dielectric material comprising a surface substantially leveled with the first surface; and
a metal layer contacting the first surface of the first semiconductor die and covering an entirety of the surface of the dielectric material, wherein an adhesivity between the metal layer and a dicing tape is lower than an adhesivity between the dielectric material and the dicing tape.

2. The semiconductor packaged device of claim 1, further comprising a first substrate and a plurality of connectors, wherein the first semiconductor die is bonded to the first substrate through the connectors on a second surface opposite to the first surface.

3. The semiconductor packaged device of claim 2, wherein the dielectric material further surrounds the connectors and covers the substrate.

4. The semiconductor packaged device of claim 2, wherein the first substrate comprises a plurality of through vias electrically connecting the first semiconductor die with a second substrate.

5. The semiconductor packaged device of claim 1, further comprising a second semiconductor die having a first surface leveled with the first surface of the first semiconductor die, wherein the metal layer extends continuously from the first surface of the first semiconductor die and covering the first surface of the second semiconductor die.

6. The semiconductor packaged device of claim 1, wherein the metal layer is selected from a group consisting of Ti, Cu, Ni, and Al.

7. The semiconductor packaged device of claim 1, further comprising a heat spreader, wherein the metal layer is disposed between the heat spreader and the first semiconductor die.

8. The semiconductor packaged device of claim 7, further comprising a thermal interface material disposed between the metal layer and the heat spreader.

9. The semiconductor packaged device of claim 1, wherein the metal layer comprises a thickness from about 0.1 μm to about 1 μm.

10. The semiconductor packaged device of claim 1, wherein the metal layer is electrically insulated from the first semiconductor die.

11. A semiconductor packaged device, comprising:
a semiconductor die;
a first dielectric material surrounding the semiconductor die laterally and including a sidewall facing away from the semiconductor die; and
a metal layer contacting a top surface of the semiconductor die and covering an entirety of an upper surface of the first dielectric material, wherein a sidewall of the capping metal layer is aligned with the sidewall of the first dielectric material, wherein an adhesivity between the metal layer and a dicing tape is lower than an adhesivity between the dielectric material and the dicing tape.

12. The semiconductor packaged device of claim 11, further comprising a second dielectric material covering a sidewall of the metal layer.

13. The semiconductor packaged device of claim 11, wherein a surface energy between the metal layer and a dry film is smaller than a surface energy between the first dielectric material and the dry film.

14. The semiconductor packaged device of claim 11, wherein the metal layer comprises a thermal conductivity between about 100 Watt/m*K and about 400 Watt/m*K.

15. The semiconductor packaged device of claim 12, comprising a thermal interface material over the second dielectric material and the metal layer.

16. The semiconductor packaged device of claim 15, wherein the thermal interface material comprises a melting temperature less than the metal layer.

17-20. (canceled)

21. A semiconductor packaged device, comprising:
a first semiconductor die;
a second semiconductor die spaced apart from the first semiconductor die;
a first dielectric material surrounding the first semiconductor die and the second semiconductor die; and
a metal layer contacting the first semiconductor die and the second semiconductor die and covering an entirety of an upper surface of the first dielectric material, and the metal layer is configured to be in contact with a dicing tape, wherein an adhesivity between the metal layer and the dicing tape is lower than an adhesivity between the first dielectric material and the dicing tape.

22. The semiconductor packaged device of claim 21, further comprising a second dielectric material encapsulating the first semiconductor die, the second semiconductor die and the first dielectric material, the second dielectric material has a top leveled with a top surface of the first dielectric material.

23. The semiconductor packaged device of claim 22, further comprising a thermal interface material covering the metal layer and the second dielectric material.

24. The semiconductor packaged device of claim 23, wherein the thermal interface material has a bottom portion leveled with a bottom portion of the second dielectric material.
